(19) United States
(12) Patent Application Publication
(10) Pub. No.: US 2024/0402372 A1
(43) Pub. Date: Dec. 5, 2024

(54) Modeling Complex Well Completions

(71) Applicant: Saudi Arabian Oil Company, Dhahran (SA)

(72) Inventors: Tareq Shaalan, Dhahran (SA); Ali H. Dogru, Dhahran (SA); Zhen Chen, Dhahran (SA)

(21) Appl. No.: 18/326,299

(22) Filed: May 31, 2023

(51) Int. Cl. G01V 1/28; G06F 30/23; G06T 17/20

(52) U.S. Cl. CPC G01V 1/282; G06F 30/23; G06T 17/20

(57) ABSTRACT

Methods and systems for modeling complex well completions include identifying a well that is a candidate for receiving a complex well completion and generating initial configuration data representing completion devices for the well. The well is modeled as a set of wellbore segments defining a well network based on the initial configuration data. The well network is integrated into a reservoir simulation grid by locating the wellbore segments within the simulated reservoir at particular locations within the reservoir simulation grid. A portion of the well network within a first area of the reservoir is selected comprising at least one wellbore segment. The reservoir simulation grid is refined within the first area and coarsened outside the first area. A simulation of the reservoir simulator is executed generating production data representing the production from the well. A simulated production profile of the well is rendered for display.

### TECHNICAL FIELD

The present disclosure relates to modeling complex well completions.

### BACKGROUND

Complex wells include wells designed with engineering or application challenges outside conventional practices. Completions designed for complex wells can include mechanical devices. For example, flow control devices (FCDs), such as inflow control devices (ICDs) and interval control valves (ICVs), have many applications in both conventional reservoirs and unconventional reservoirs (for example, any reservoir that requires special recovery operations outside conventional operating practices, such as tight-gas sands, gas and oil shales, coalbed methane, heavy oil and tar sands, and gas-hydrate deposits). FCDs can be used to mitigate water or gas-coning problems for mature fields in conventional reservoirs, alleviate premature water breakthrough in naturally fractured reservoirs, and optimize steam distribution in heavy oil reservoirs. Example complex wells that use FCDs, for example, to control intelligent completions, include ultra-deep (for example, with drilling depths up to 15 kilometers (km)) and long horizontal extended-reach drilling (ERD) wells (for example, with reservoir contacts up to or greater than 10 km), wells with completions in multi-layer reservoirs (for example, Maximum Reservoir Contact (MRC) wells with an aggregate reservoir contact in excess of 5 km), and multilateral wells with isolated compartments of varying pressure.

### SUMMARY

This disclosure describes methods and systems for modeling complex well completions. Complex well completions include mechanical devices, for example, FCDs, installed in the wellbore that are configured to control production from the well. A data processing system, such as a computer or a set of computing devices, identifies a well that is a candidate for receiving the complex well completion. The data processing system initializes a configuration for the complex well completion. For example, the data processing system initializes a number and type of FCDs for including in the well. FCDs can include ICDs, ICVs, packers, and electronic submersible pumps. The data processing system also initializes a location of the FCDs along the well trajectory. The data processing system generates a model of that includes a complex well network, and generation of the model is based on the initialized configuration. The data processing system integrates the complex well network into a reservoir simulation grid by locating the wellbore segments within the simulated reservoir at particular locations within the reservoir simulation grid. The data processing system refines the simulation grid (e.g., increases a number of grid elements of the simulation grid associated with data to be processed in the simulation to increase the spatial resolution of the simulation) in an area of interest near the identified well. Outside the area of interest, the data processing system coarsens the simulation grid (e.g., decreases a number of grid elements of the simulation grid to decrease the spatial resolution of the simulation). The data processing system simulates a production from the identified well using the reservoir simulator. The data processing system renders a simulated production profile of the identified well. In some implementations, the data processing system can generate one or more control instructions for performing well drilling by one or more remote devices. In some implementations, these instructions are transmitted to or are incorporated into well plans that guide and/or other operations at an existing reservoir. In some implementations, the data processing system can generate one or more control instructions for controlling remote completion devices installed in a well. In some implementations, these instructions are transmitted to completion devices or are incorporated into well plans that guide installation of the well completion and/or other operations at an existing reservoir.

Implementations of the systems and methods of this disclosure can provide various technical benefits. Horizontal and multilateral well drilling technology and complex wellbore configurations resulting from implementations of intelligent completion systems has resulted in the development of increasingly complex well models for use in reservoir simulations. The increasingly complex well models require more data computation, which results in longer computation times and requires greater computing resources to simulate accurate production of hydrocarbons from the well. The data processing system can incorporate an increased variety of designs of mechanical devices in the complex completions, which can further increase a computational complexity of the simulation. When using a reservoir model having thousands or millions of grid elements, simulating and optimizing ICDs and compartments within the wellbore is computationally expensive. The simulation accommodates both the large geographic scale (many kilometers or miles) of the reservoir and the small scales (centimeters or inches) of the devices or compartments of the complex well design.

To overcome these challenges, the systems and methods of this disclosure model complex wells using a segmented well network approach that can incorporate a large variety of completion devices. The data processing system couples the well network model to a reservoir simulation by linking perforated links of the well network model with grid elements of the simulation grid associated with the location of the perforated link in the well. The data processing system refines the simulation grid for selected segments of the complex well at a dynamically defined area of interest around the identified well segments. The data processing system also coarsens the simulation grid at simulated geographic locations outside the dynamically defined areas of interest around the identified well segments to reduce the number of computations to simulate the reservoir. In this manner, the data processing system preserves fidelity of the simulation in the dynamically defined area of interest while reducing overall computation requirements. In some implementations, the computation time can be reduced by reduced by 3X to 5X. For a single execution of the reservoir simulator, the data processing system uses 50% to 60% fewer computer resources (e.g., processors and memory) as compared with conventional methods. The data processing system can optimize the well completion configuration by running multiple iterations of the reservoir simulator with the reduced computation time and improve the accuracy of the simulations at the identified areas of interest, relative to a coarser simulation that would be performed without generation of the complex well model.

In one aspect, a method for modeling complex well completions includes identifying a well that is a candidate for receiving a complex well completion, the complex well completion including completion devices configured to alter a production from the well; generating initial configuration data representing completion devices for the well; modeling the well as a set of wellbore segments, the set of wellbore segments defining a well network, wellbore segments of the set of wellbore segments being modeled to represent completion devices based on the initial configuration data; integrating the well network into a reservoir simulation grid by locating the wellbore segments within the simulated reservoir at particular locations within the reservoir simulation grid; selecting a portion of the well network including at least one wellbore segment, the portion of the well network within a first area of the reservoir simulation grid; refining the reservoir simulation grid within the first area that includes the selected at least one wellbore segment; coarsening the reservoir simulation grid in a second area of the reservoir simulation grid outside of the first area that includes the at least one wellbore segment; executing a simulation of the reservoir simulator, the simulation generating production data representing the production from the well, where the refining provides data at a high resolution at the first area, and where the coarsening enables a reduction in processing resources relative to the processing resources required for the first area; and rendering for display a simulated production profile of the well.

In one aspect, a system for modeling complex well completions includes at least one processor; and a memory storing instructions that, when executed by the at least one processor, cause the at least one processor to perform operations including identifying a well that is a candidate for receiving a complex well completion, the complex well completion including completion devices configured to alter a production from the well; generating initial configuration data representing completion devices for the well; modeling the well as a set of wellbore segments, the set of wellbore segments defining a well network, wellbore segments of the set of wellbore segments being modeled to represent completion devices based on the initial configuration data; integrating the well network into a reservoir simulation grid by locating the wellbore segments within the simulated reservoir at particular locations within the reservoir simulation grid; selecting a portion of the well network including at least one wellbore segment, the portion of the well network within a first area of the reservoir simulation grid; refining the reservoir simulation grid within the first area that includes the selected at least one wellbore segment; coarsening the reservoir simulation grid in a second area of the reservoir simulation grid outside of the first area that includes the at least one wellbore segment; executing a simulation of the reservoir simulator, the simulation generating production data representing the production from the well, where the refining provides data at a high resolution at the first area, and where the coarsening enables a reduction in processing resources relative to the processing resources required for the first area; and rendering for display a simulated production profile of the well.

In one aspect, one or more non-transitory machine-readable storage devices storing instructions for modeling complex well completions, the instructions being executable by one or more processors, to cause performance of operations including identifying a well that is a candidate for receiving a complex well completion, the complex well completion including completion devices configured to alter a production from the well; generating initial configuration data representing completion devices for the well; modeling the well as a set of wellbore segments, the set of wellbore segments defining a well network, wellbore segments of the set of wellbore segments being modeled to represent completion devices based on the initial configuration data; integrating the well network into a reservoir simulation grid by locating the wellbore segments within the simulated reservoir at particular locations within the reservoir simulation grid; selecting a portion of the well network including at least one wellbore segment, the portion of the well network within a first area of the reservoir simulation grid; refining the reservoir simulation grid within the first area that includes the selected at least one wellbore segment; coarsening the reservoir simulation grid in a second area of the reservoir simulation grid outside of the first area that includes the at least one wellbore segment; executing a simulation of the reservoir simulator, the simulation generating production data representing the production from the well, where the refining provides data at a high resolution at the first area, and where the coarsening enables a reduction in processing resources relative to the processing resources required for the first area; and rendering for display a simulated production profile of the well.

Implementations of these aspects can include one or more of the following features.

In some implementations, these aspects include changing values of parameters of the configuration of completion devices; iteratively performing the executing and the changing until a value of an objective function meets a prespecified criterion; and selecting a final configuration of completion devices based on a latest iteration of performing meeting the prespecified criterion.

In some implementations, parameters of the configuration of completion devices include at least one of locations of completion devices, types of completion devices, and a number of completion devices.

In some implementations, the objective function includes at least one of a water cut, a total oil production, a net present value of oil in the reservoir, an oil production in compartments of the well, a gas breakthrough, and a water breakthrough.

In some implementations, these aspects include resetting the simulation grid to an original resolution; integrating the final configuration of completion devices into the simulation grid by locating the well segments within the simulated reservoir at particular locations within the reservoir simulation grid; and executing a simulation of the reservoir simulator with the simulation grid at the original resolution.

In some implementations, these aspects include rendering for display a three-dimensional visualization of well segments and completion devices of the identified well.

In some implementations, these aspects include generating commands to adjust settings of completion devices installed in the identified well based on the simulated production.

In some implementations, the first area includes reservoir simulation grid points within a specified radius surrounding the location of the identified well within the reservoir simulation grid.

The details of one or more embodiments of these systems and methods are set forth in the accompanying drawings and the description below. Other features, objects, and advantages of these systems and methods will be apparent from the description and drawings, and from the claims.

### DESCRIPTION OF DRAWINGS

FIG. 1 illustrates a well with uneven production along the length of the well.

FIG. 2 illustrates an example configuration of mechanical devices for a complex completion.

FIG. 3 is a flow chart of an example method for modeling complex well completions.

FIG. 4A illustrates an example complex well network model.

FIGS. 4B-4C illustrate example simulation grids with refinement and coarsening.

FIG. 5 illustrates a schematic of a system for modeling a complex well completion.

FIG. 6 illustrates an example production profile for a complex well.

FIG. 7 illustrates an example three-dimensional visualization of a complex well completion.

FIGS. 8-9 illustrate example performance of a well with a complex completion configured using an implementation of the method of FIG. 3.

FIG. 10 is a block diagram illustrating an example computer system used to provide computational functionalities associated with described algorithms, methods, functions, processes, flows, and procedures according to some implementations of the present disclosure. Like reference symbols in the various drawings indicate like elements.

### DETAILED DESCRIPTION

This specification describes methods and systems for modeling complex well completions. A parallel complex wellbore model is designed and implemented for use in a full-cycle process to optimize the production in real operation. A data processing system, such as a computer or a control system, identifies a well to receive a complex completion. The data processing system generates an initial configuration of completion devices for the well. The initial configuration includes the location, number and types of completion devices in the well. Example completion devices include ICDs, ICVs, submersible pumps, and packers. In some implementations, the data processing system can adjust the initial configuration of completion devices based on user input received through a graphical interface (such as for challenging reservoirs). Generally, the data processing system generates the initial configuration based on user input (such as types and locations of completion devices within the well). The data processing system simulates production from the complex well model with a coupled massively parallel reservoir simulator executing on thousands to tens of thousands of parallel processes. The data processing system produces detailed visualizations of the complex well simulation results to evaluate the performance of the advanced completion devices. The complex well modeling process aids production optimization throughout the lifecycle of the well including optimization of the initial design of the well completion and optimization of completion device settings during production. The modeling and simulation cycle can be repeated many times for a single well. After the initial well completion design is finalized, subsequent modeling and simulation cycles can use the already developed well network model to optimize parameter settings of the completion devices installed in the well based on current well performance and prior simulation results. The results from the process can provide guidance for making operational decisions at a physical well in the reservoir that is simulated. The operational decisions can include controlling the location of well drilling and controlling well geometry. The operational decisions can also include controlling well completion devices installed in a well or controlling the installation of completion devices.

With the advanced completion, the complex well model of the data processing system described herein enable, for the complex well, an improved oil recovery and delayed water production. In many cases, when a well reaches high water cut, a sidetrack is drilled. Advanced completions are considered in the new drilled sidetrack to mitigate the water coning problem. By adjusting the inflow on individual zones or on individual laterals, it is possible to reduce water or gas production and increase the profitability of a well or the reservoir. The data processing system herein enables designs of advanced completions based on simulated production from the well. The data processing system can model many types of completion devices and iterate the reservoir simulations because of simulation grid refinement and coarsening that reduces the computation time required by the simulation.

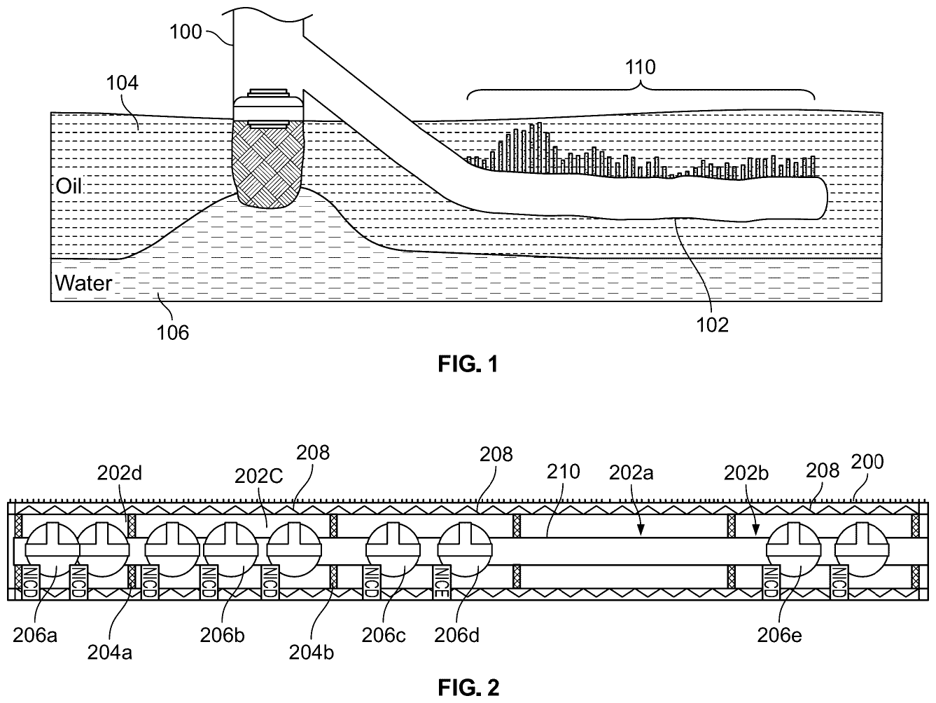

FIG. 1 illustrates a well 100 with a lateral side-track 102. The lateral side-track 102 extends horizontally into an oil rich zone 104 of a subterranean formation. Underneath the oil rich zone 104 is a water saturated zone 106. The lateral side-track 102 is perforated to permit oil to enter the well. Without complex completion devices, the fluid production 110 along the length of the lateral side-track is uneven.

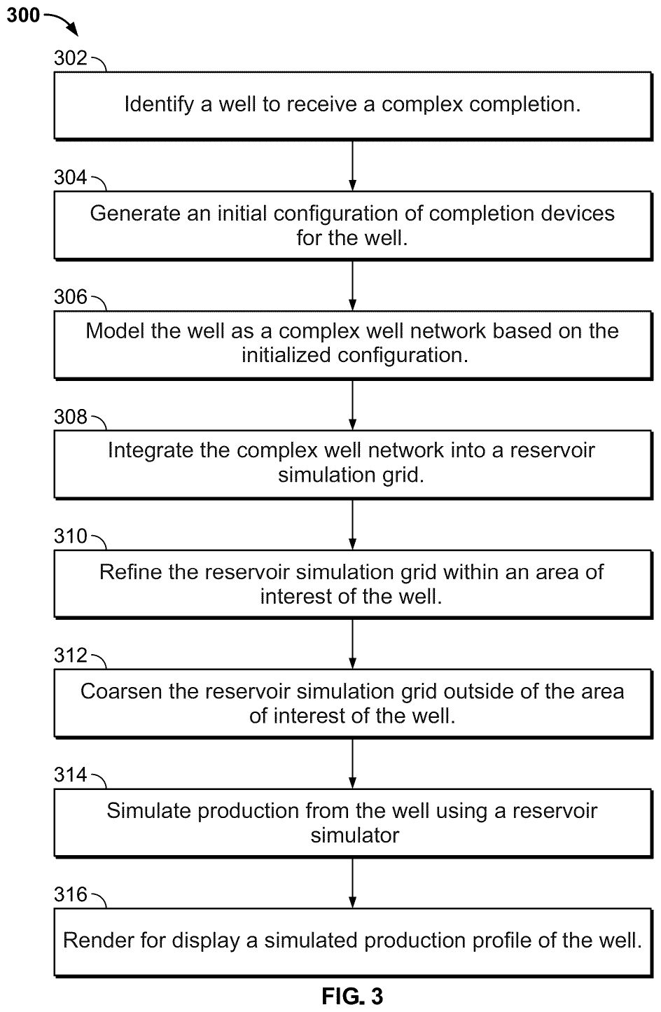

FIG. 2 illustrates an example design for a complex completion that can be installed in a well (e.g., the well 100 of FIG. 1). The wellbore 200 is divided into compartments 202a-d. These compartments can also be called segments 202. The compartments 202a-d are isolated from each other by packers 204a-b. Within each compartment 202a-d, a number of ICDs 206a-e can be installed depending on the predicted production of the individual compartments 202a-d. Perforations 208 in the walls of the wellbore 200 allow fluid to pass from the formation into the well. The ICDs 206a-e can be designed to equalize the flow of fluids into the production tubing 210.

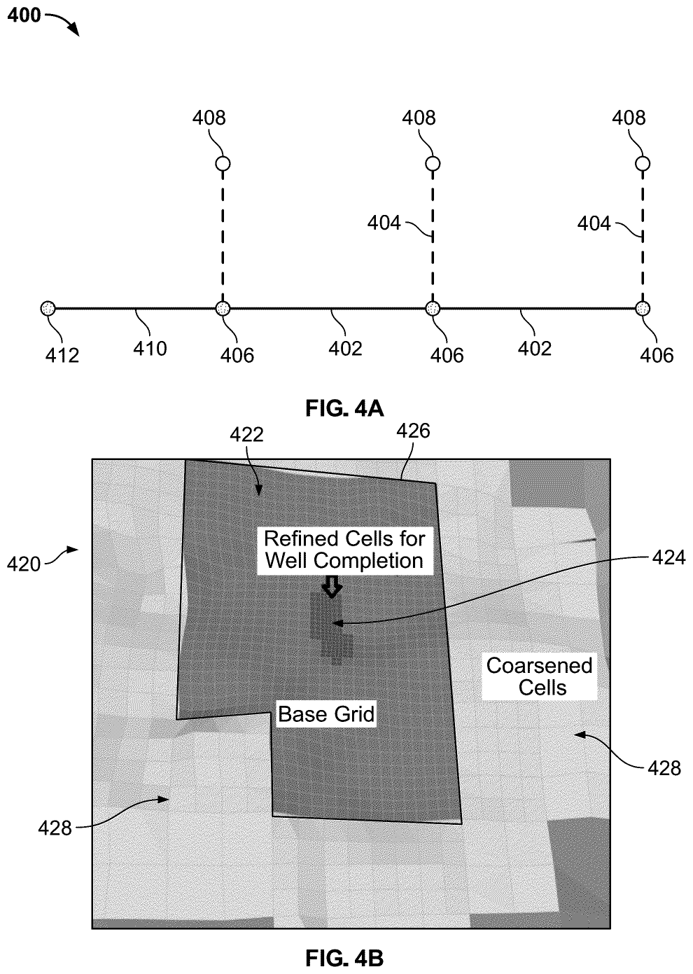

FIG. 3 is a flow chart of an example method 300 for modelling a complex well completion. The method 300 is a full-cycle process for using complex well modeling to optimize production of the well. Complex completions can mitigate early water breakthrough and equalize the production along the wellbore. A data processing system couples a model of a well completion design with a reservoir simulator to simulate the production from the well. The data processing system can alter parameters of the completion design to reach a specified production objective.

The data processing system identifies a well to receive a complex completion (302). The method 300 can be applied to many types of wells including newly drilled wells and sidetracks of existing wells. Candidate wells are typically located in a challenging reservoir, and the oil productivity is low due to heterogeneous geological properties and high water cut or high gas production. The data processing system identifies wells automatically by defining a criterion in the reservoir simulation. For example, the data processing system can identify branches and wells having high water cut over 80%. In some implementations, the data processing takes as input a constraint or control parameter such as water cut or gas/oil ratio (GOR). The data processing system outputs identified wells or branches of wells to receive complex completions.

The data processing system generates an initial configuration of completion devices for the identified well (304). There are many types and configurations of completion devices that can be selected for a well completion. The data processing system can base the initial configuration of devices on the distribution of static properties (e.g., permeability and porosity) and dynamic properties (e.g., oil saturation, and water saturation) around the wellbore. The general principle for completion design is to separate the wellbore into compartments (e.g., 202), within each compartment the reservoir properties are more homogeneous. Packers (e.g., 204) are used to isolate the compartments. Advanced devices such as ICDs (e.g., 206) and sliding ICVs are placed inside compartments. In some implementations, the type and number of mechanical devices within each compartment can be adjustable parameters in an optimization of the production. The data processing system generates text based configuration files that include data files and device files. The data files include the trajectory of the well and the location of the devices. The device files include physical models for each device (e.g., orifice ICD and autonomous ICD).

In some implementations, a user can design the advanced completion using a graphical user interface (GUI) tool to interface with the data processing system. Using the GUI, the user can select devices and locations of the devices within the wellbore. The data processing system generates the text based configuration files based on the user selected design in the GUI. Using a GUI to design a completion can reduce user error as compared with text based design methods because the user can visually verify the layout of the completion devices. Users can manually tune the parameters of the devices using the GUI. The data processing system can also perform an optimization (e.g., by using a gradient-descent or evolution based algorithm) on the parameters of the devices selected by a user using the GUI.

The data processing system models the well as a complex well network based on the initial configuration (306). The general network concept represents wells using links and nodes. Each link represents a wellbore segment, a completion connection (e.g., a perforation), or a mechanical device (e.g., ICD, ICV, compartment, electronic submersible pump, etc.). A node is the connection of two or more links. The general network concept better handles complex topology of complex wells (e.g., multi-branching, loops, and multiple exits) as compared with other methods. The data processing system can model the performance of many types of completion devices including, for example, multi-position ICVs. In some implementations, the data processing system uses head-curve methods to model electronic submersible pumps.

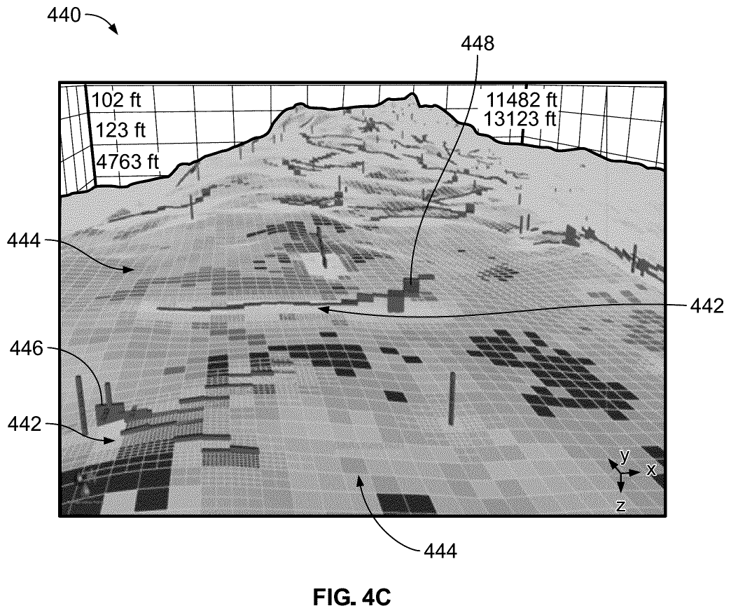

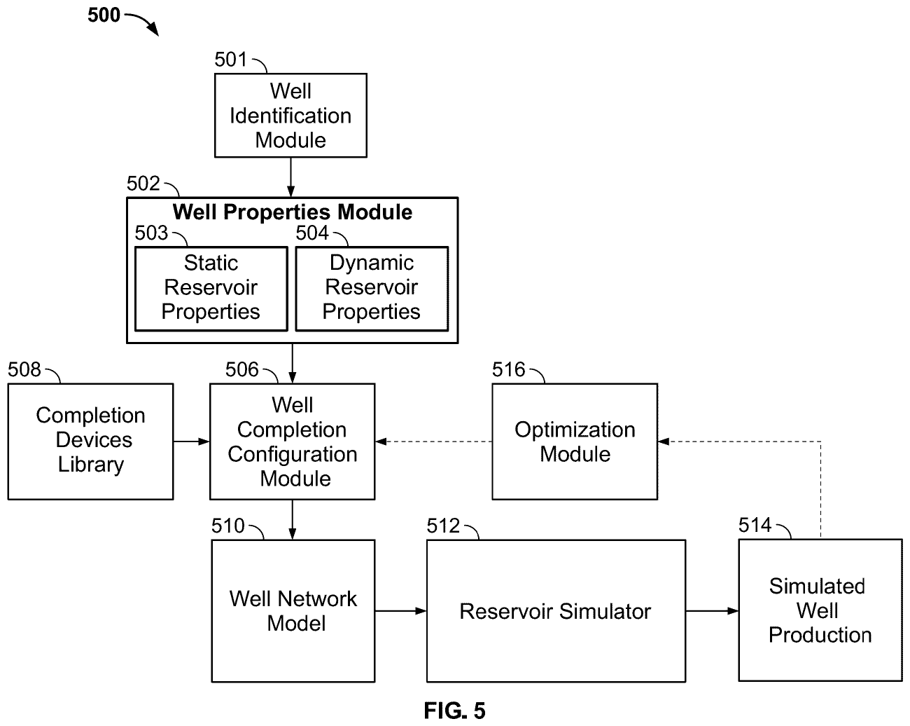

FIG. 4A illustrates an example complex well network 400 represented by a graph without any mechanical devices. The solid lines 402 are links representing wellbore trajectories and dashed lines 404 are links representing perforations. Nodes represent connection points of the links. Nodes 406 represent connections between wellbore trajectory links 402. Nodes 408 represent connections to perforation links 404. The first link 410 and node 412 are the well source/sink.

Turning back to FIG. 3 and method 300, the data processing system integrates the complex well network into a reservoir simulation grid (308). The complex well network can be coupled with the reservoir simulation grid using, for example, explicit coupling, sequential coupling, or implicit coupling. In some implementations, implicit coupling can be more robust and faster than the other methods. The data processing system solves the wellbore network model together as one system with the reservoir simulation grid. The data processing system updates the boundary conditions of the wellbore network model for each iteration.

The data processing system refines the reservoir simulation grid within an area of interest of the well (310). The data processing system can define the area of interest as a radius surrounding the well, In other implementations, the data processing system can use a mask array to define the area of interest. For example, a property mask array can define fractures and faults of the reservoir. The data processing system refines the simulation grid by decreasing the length between nodes of the grid thereby increasing the number of elements of the reservoir simulation grid near the well. For example, the reservoir simulation grid can be refined to a level that each device (e.g., ICV, ICD) in the complex well network model is represented in a separate cell of the simulation grid.

The data processing system coarsens the reservoir simulation grid outside of the area of interest (312). The data processing system increases the length between nodes of the grid decreasing the number of elements far from the well. The data processing system coarsens the grid outside the area of interest to decrease the computation time to run the simulation without compromising accuracy in the area of interest. In some implementations, the data processing system coarsens the grid by one level (e.g., coarsening the grid by dividing the number of cells in each dimension by 2). One level of coarsening reduces the overall number of cells by 4 away from area of interest. In some implementations, the data processing system, coarsens the grid with two levels of coarsening (e.g., dividing the number of cells in each dimension by 22=4) reducing the total number of cells by 16 away from area of interest. In some implementations, the data processing system gradually coarsens the grid (e.g., the number of grid cells gradually decreases away outside the area of interest). In some implementations, the data processing system abruptly coarsens the simulation grid (e.g., the number of grid cells abruptly decreases outside of the area of interest).

FIG. 4B illustrates an example simulation grid 420 with refinement and coarsening. The original simulation grid (e.g., base grid) includes base grid cells 422 with a base resolution. The well grid cells 424 surrounding the identified well have been refined with a higher resolution than the base resolution. This is shown as the well grid cells 424 having a smaller size than the base grid cells 422. Outside the area of interest 426, the outer grid cells 428 are coarsened with a lower resolution than the base resolution.

FIG. 4C illustrates another example simulation grid 440 showing local areas of refinement 442 and areas of coarsening 444. The local areas of refinement 442 occur in areas around objects of interest (e.g., 446, 448). Outside the areas of interest, the grid cells increase in size in the areas of coarsening 444. In this manner, the data processing system can generate data representing well production from multiple wells using a single execution of the reservoir simulator.

Turning back to method 300 in FIG. 3, the data processing system executes a simulation of a reservoir simulator generating production data representing production from the well (314). For example, the data processing system can use a massively parallel reservoir simulator with a million or more cells in the simulation grid. In some implementations, the data processing system can use other reservoir simulators.

In some implementations, the data processing system uses the complex network model uses a hybrid parallel technique. The data processing system executes the well level using message passing interface (MPI) parallel processes, where each process has its own memory space and executes independently from other processes. The data processing system executes the segment level using open multi-processing (OpenMP) parallel threads, where processes exchange data by passing messages to each other. In this manner the both the wells and segments are processed in parallel.

The data processing system renders for display a simulated production profile of the well (316). The data processing system can render for display visualizations that represent the performance of the well. Simulation results can be displayed to field management engineers for operational decision making. The visualizations rendered by the data processing system can be used by engineers for detailed evaluation of the complex well performance.

In some implementations, the data processing system adjusts values of parameters of the configuration of completion devices. Parameters of the configuration of completion devices that can be adjusted include, for example, the number, type, and location of ICDs, the number of nozzles in individual ICDs, frequency of adjusting ICD parameters, and parameters associated with the area of interest (e.g., radius or mask size) in the simulation grid. The data processing system can adjust the values of the parameters based on an optimization algorithm, for example, a gradient descent or evolution based algorithm. Constraints on the values of the parameters can be provided by a user.

The data processing system can optimize the design of the well completion by iteratively performing the steps of simulating the reservoir and adjusting values of parameters. The data processing system can calculate the value of an objective function during each iteration to assess the performance of the well completion. Examples of objective functions include a water cut, a total oil production, a net present value of oil in the reservoir, an oil production in compartments of the well, a gas breakthrough, and a water breakthrough. The data processing system can continue iterations until the objective function meets a specified criterion. In some cases, the specified criterion can include a relative difference in the value of the objective function between the previous iteration and the current iteration. In some cases, the specified criterion can include the value of the objective function exceeding a specified value. In some cases, the specified criterion can include the value of the objective function being less than a specified value. In some cases, the specified criterion can be an absolute value of the change in the objective function. In some cases, the specified criterion can be a fixed number of iterations.

In some implementations, the data processing system selects a final configuration of completion devices for which the objective function satisfies the specified criterion. The data processing system can reset the simulation grid to an original resolution (e.g., the resolution of the simulation grid prior to refinement and coarsening). The data processing system integrates the final configuration with the simulation grid. The data processing system simulates the production from the well using the reservoir simulator with the simulation grid at the original resolution. In this manner, the data processing system optimizes the completion using a proxy coarsened model, and then the data processing system simulates the optimized completion using the original reservoir model for prediction.

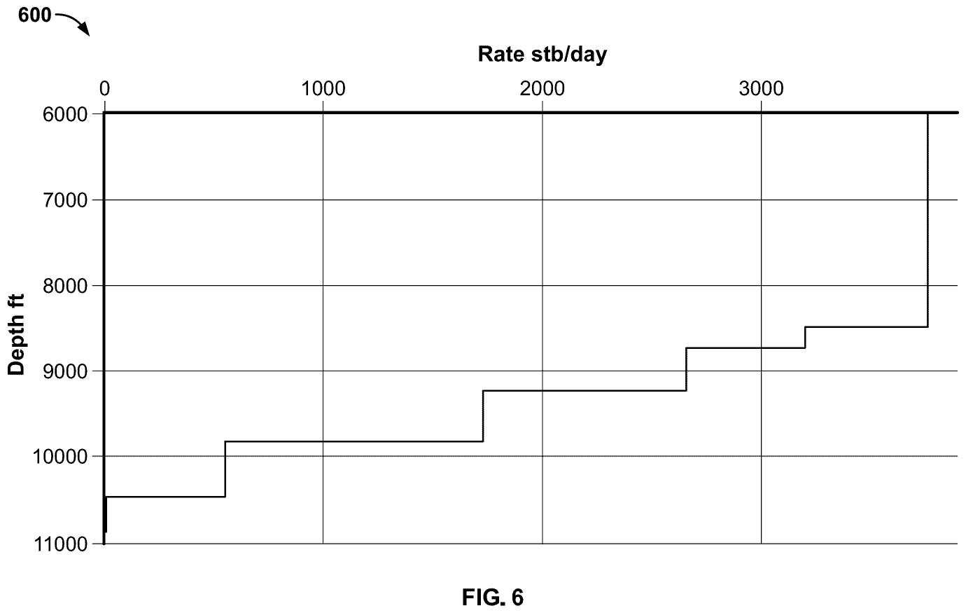

FIG. 5 shows a schematic of an example system 500 for modeling complex well completions. The well identification module 501 identifies candidate wells that can receive complex well completions. The well properties module 502 selects static reservoir properties 503 and dynamic reservoir properties 504 corresponding to the identified well. The well completion configuration module 506 receives input from the well properties module 502 and the completion devices library 508. The completion devices library 508 includes data representing various completion devices (e.g., FCDs, ICDs, ICVs, packers). The well completion configuration module 506 generates data representing the configuration (e.g., type, number, location) of completion devices. The output from the well completion configuration module 506 is fed into the well network model 510. The well network model generates a set of well segments representing the configuration of completion devices. The well segments are linked together to form a well network. The well network model 510 is sent to the reservoir simulator 512 where the well segments are integrated with elements of the reservoir simulation grid at locations in the simulation grid corresponding to the locations of the well segments in the reservoir. The reservoir simulator 512 is executed to simulate production from the well. The output of the reservoir simulator 512 is the simulated well production 514. The simulated well production 514 can be rendered for display to users. The simulated well production 514 can be fed to an optimization module 516 that is configured to change values of the configuration of the well completion to alter the simulated well production. The optimization can be performed iteratively cycling from the well completion configuration module 506 to the well network model 510 to the reservoir simulator 512 to the simulated well production 514 to the optimization module 516 and back to the well completion configuration module 506. This optimization cycle can be repeated until the simulated well production 514 reaches a specified target value or passes a specified threshold.

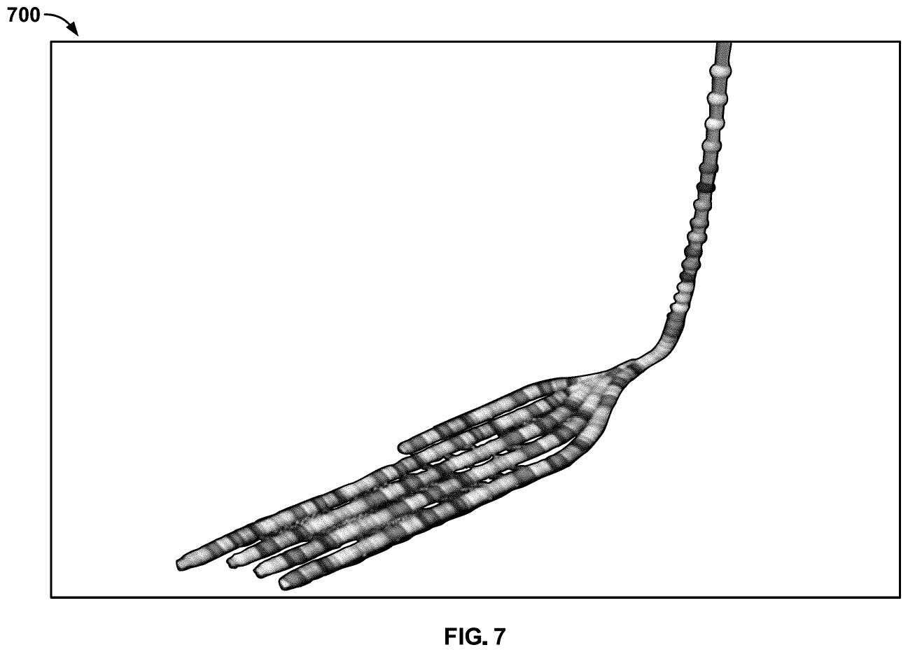

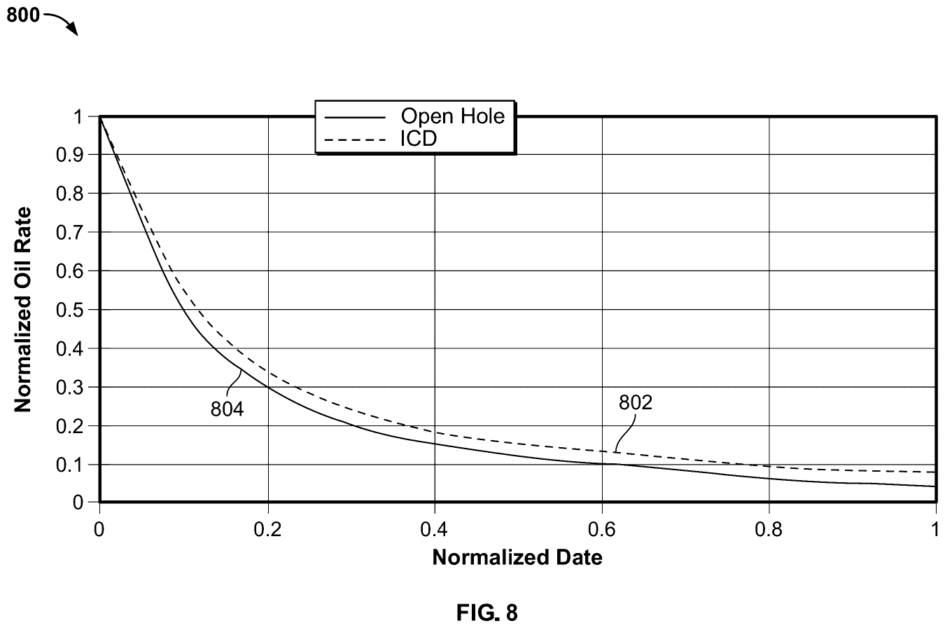

FIGS. 6-7 show examples of visualizations produced by the data processing system as outputs of the reservoir simulation. These visualizations can help engineers to perform detailed analysis on the simulation results and implement the well completion configuration.

FIG. 6 shows an example of production profile along the wellbore. This visualization can be used to evaluate the performance of the well at each interval. The production in stb/day is plotted against the depth in feet of the well. The data processing system renders production profiles for display similar to that shown in FIG. 6 at the end of the simulation.

FIG. 7 shows an example of a three-dimensional (3D) visualization 700 of well segments and devices. The visualization 700 shows the smart completion devices (e.g., ICD/ICVs) along the well trajectories. The data processing system can render each type of device in a different color allowing a user to easily identify the devices and locations of the devices in the designed configuration.

Based on the configuration of completion devices selected by application of the method 300, complex well completions can be implemented in the wells. In implementations where the well completion has previously been implemented, the data processing system can determine settings of the installed devices that meet a specified criteria and generate control commands to adjust the settings of the installed devices to match the determined settings.

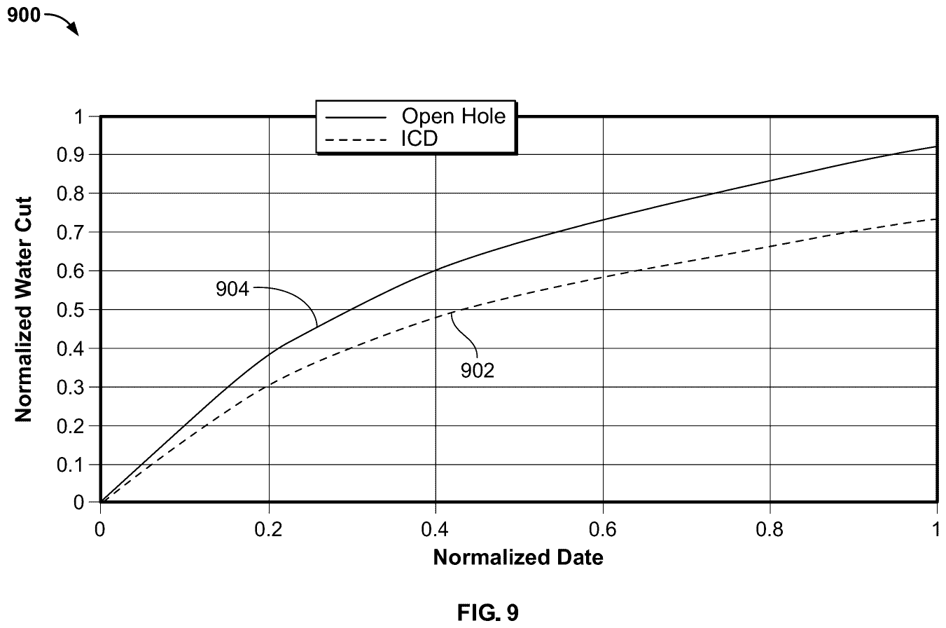

FIGS. 8-9 show results from implementations of the method 300 to design and optimize complex well completions. The well completion was designed and optimized using an implementation of the method 300. The designed well completion was installed in a newly drilled side-track of an existing well. FIG. 8 shows an example plot 800 illustrating higher oil production using the designed completion with ICDs 802 compared to the oil production in the open hole completion 804 (e.g., no devices used). FIG. 9 shows an example plot 900 illustrating the lower water cut with the usage of ICDs 902 compared with the open hole completion 904 in the same well as FIG. 8.

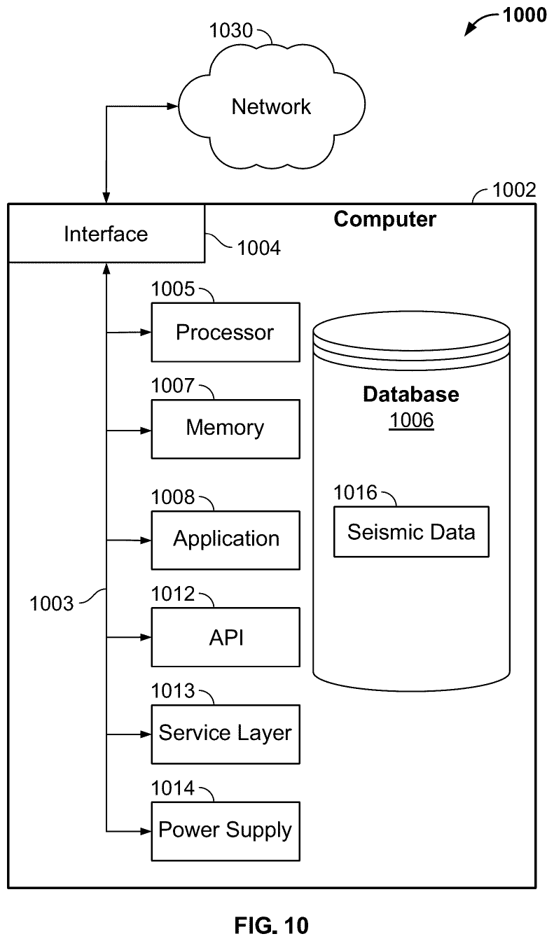

FIG. 10 is a block diagram of an example computer system 1000 used to provide computational functionalities associated with described algorithms, methods, functions, processes, flows, and procedures described in the present disclosure, according to some implementations of the present disclosure. The illustrated computer 1002 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1002 can include input devices such as keypads, keyboards, and touch screens that can accept user information. Also, the computer 1002 can include output devices that can convey information associated with the operation of the computer 1002. The information can include digital data, visual data, audio information, or a combination of information. The information can be presented in a graphical user interface (UI) (or GUI).

The computer 1002 can serve in a role as a client, a network component, a server, a database, a persistency, or components of a computer system for performing the subject matter described in the present disclosure. The illustrated computer 1002 is communicably coupled with a network 1030. In some implementations, one or more components of the computer 1002 can be configured to operate within different environments, including cloud-computing-based environments, local environments, global environments, and combinations of environments.

At a high level, the computer 1002 is an electronic computing device operable to receive, transmit, process, store, and manage data and information associated with the described subject matter. According to some implementations, the computer 1002 can also include, or be communicably coupled with, an application server, an email server, a web server, a caching server, a streaming data server, or a combination of servers.

The computer 1002 can receive requests over network 1030 from a client application (for example, executing on another computer 1002). The computer 1002 can respond to the received requests by processing the received requests using software applications. Requests can also be sent to the computer 1002 from internal users (for example, from a command console), external (or third) parties, automated applications, entities, individuals, systems, and computers.

Each of the components of the computer 1002 can communicate using a system bus 1003. In some implementations, any or all of the components of the computer 1002, including hardware or software components, can interface with each other or the interface 1004 (or a combination of both), over the system bus 1003. Interfaces can use an application programming interface (API) 1012, a service layer 1013, or a combination of the API 1012 and service layer 1013. The API 1012 can include specifications for routines, data structures, and object classes. The API 1012 can be either computer-language independent or dependent. The API 1012 can refer to a complete interface, a single function, or a set of APIs.

The service layer 1013 can provide software services to the computer 1002 and other components (whether illustrated or not) that are communicably coupled to the computer 1002. The functionality of the computer 1002 can be accessible for all service consumers using this service layer. Software services, such as those provided by the service layer 1013, can provide reusable, defined functionalities through a defined interface. For example, the interface can be software written in JAVA, C++, or a language providing data in extensible markup language (XML) format. While illustrated as an integrated component of the computer 1002, in alternative implementations, the API 1012 or the service layer 1013 can be stand-alone components in relation to other components of the computer 1002 and other components communicably coupled to the computer 1002. Moreover, any or all parts of the API 1012 or the service layer 1013 can be implemented as child or sub-modules of another software module, enterprise application, or hardware module without departing from the scope of the present disclosure.

The computer 1002 includes an interface 1004. Although illustrated as a single interface 1004 in FIG. 10, two or more interfaces 1004 can be used according to particular needs, desires, or particular implementations of the computer 1002 and the described functionality. The interface 1004 can be used by the computer 1002 for communicating with other systems that are connected to the network 1030 (whether illustrated or not) in a distributed environment. Generally, the interface 1004 can include, or be implemented using, logic encoded in software or hardware (or a combination of software and hardware) operable to communicate with the network 1030. More specifically, the interface 1004 can include software supporting one or more communication protocols associated with communications. As such, the network 1030 or the interface's hardware can be operable to communicate physical signals within and outside of the illustrated computer 1002.

The computer 1002 includes a processor 1005. Although illustrated as a single processor 1005 in FIG. 10, two or more processors 1005 can be used according to particular needs, desires, or particular implementations of the computer 1002 and the described functionality. Generally, the processor 1005 can execute instructions and can manipulate data to perform the operations of the computer 1002, including operations using algorithms, methods, functions, processes, flows, and procedures as described in the present disclosure.

The computer 1002 also includes a database 1006 that can hold data for the computer 1002 and other components connected to the network 1030 (whether illustrated or not). For example, database 1006 can be an in-memory, conventional, or a database storing data consistent with the present disclosure. In some implementations, database 1006 can be a combination of two or more different database types (for example, hybrid in-memory and conventional databases) according to particular needs, desires, or particular implementations of the computer 1002 and the described functionality. Although illustrated as a single database 1006 in FIG. 10, two or more databases (of the same, different, or combination of types) can be used according to particular needs, desires, or particular implementations of the computer 1002 and the described functionality. While database 1006 is illustrated as an internal component of the computer 1002, in alternative implementations, database 1006 can be external to the computer 1002.

The computer 1002 also includes a memory 1007 that can hold data for the computer 1002 or a combination of components connected to the network 1030 (whether illustrated or not). Memory 1007 can store any data consistent with the present disclosure. In some implementations, memory 1007 can be a combination of two or more different types of memory (for example, a combination of semiconductor and magnetic storage) according to particular needs, desires, or particular implementations of the computer 1002 and the described functionality. Although illustrated as a single memory 1007 in FIG. 10, two or more memories 1007 (of the same, different, or combination of types) can be used according to particular needs, desires, or particular implementations of the computer 1002 and the described functionality. While memory 1007 is illustrated as an internal component of the computer 1002, in alternative implementations, memory 1007 can be external to the computer 1002.

The application 1008 can be an algorithmic software engine providing functionality according to particular needs, desires, or particular implementations of the computer 1002 and the described functionality. For example, application 1008 can serve as one or more components, modules, or applications. Further, although illustrated as a single application 1008, the application 1008 can be implemented as multiple applications 1008 on the computer 1002. In addition, although illustrated as internal to the computer 1002, in alternative implementations, the application 1008 can be external to the computer 1002.

The computer 1002 can also include a power supply 1014. The power supply 1014 can include a rechargeable or non-rechargeable battery that can be configured to be either user- or non-user-replaceable. In some implementations, the power supply 1014 can include power-conversion and management circuits, including recharging, standby, and power management functionalities. In some implementations, the power-supply 1014 can include a power plug to allow the computer 1002 to be plugged into a wall socket or a power source to, for example, power the computer 1002 or recharge a rechargeable battery.

There can be any number of computers 1002 associated with, or external to, a computer system containing computer 1002, with each computer 1002 communicating over network 1030. Further, the terms “client,” “user,” and other appropriate terminology can be used interchangeably, as appropriate, without departing from the scope of the present disclosure. Moreover, the present disclosure contemplates that many users can use one computer 1002 and one user can use multiple computers 1002.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example LINUX, UNIX, WINDOWS, MAC OS, ANDROID, or IOS.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

A number of embodiments of these systems and methods have been described. Nevertheless, it will be understood that various modifications may be made without departing from the spirit and scope of this disclosure. Accordingly, other embodiments are within the scope of the following claims.

What is claimed is:

1. A method for modeling complex well completions, the method comprising:
identifying a well that is a candidate for receiving a complex well completion, the complex well completion including completion devices configured to alter a production from the well;
generating initial configuration data representing completion devices for the well;
modeling the well as a set of wellbore segments, the set of wellbore segments defining a well network, wellbore segments of the set of wellbore segments being modeled to represent completion devices based on the initial configuration data;
integrating the well network into a reservoir simulation grid by locating the wellbore segments within the simulated reservoir at particular locations within the reservoir simulation grid;
selecting a portion of the well network comprising at least one wellbore segment, the portion of the well network within a first area of the reservoir simulation grid;
refining the reservoir simulation grid within the first area that includes the selected at least one wellbore segment;
coarsening the reservoir simulation grid in a second area of the reservoir simulation grid outside of the first area that includes the at least one wellbore segment;
executing a simulation of the reservoir simulator, the simulation generating production data representing the production from the well, wherein the refining provides data at a high resolution at the first area, and wherein the coarsening enables a reduction in processing resources relative to the processing resources required for the first area; and
rendering for display a simulated production profile of the well.

2. The method of claim 1, further comprising:
changing values of parameters of the configuration of completion devices;
iteratively performing the executing and the changing until a value of an objective function meets a prespecified criterion; and
selecting a final configuration of completion devices based on a latest iteration of performing meeting the prespecified criterion.

3. The method of claim 2, wherein parameters of the configuration of completion devices comprise at least one of locations of completion devices, types of completion devices, and a number of completion devices.

4. The method of claim 2, wherein the objective function comprises at least one of a water cut, a total oil production, a net present value of oil in the reservoir, an oil production in compartments of the well, a gas breakthrough, and a water breakthrough.

5. The method of claim 2, further comprising:
resetting the simulation grid to an original resolution;
integrating the final configuration of completion devices into the simulation grid by locating the well segments within the simulated reservoir at particular locations within the reservoir simulation grid; and
executing a simulation of the reservoir simulator with the simulation grid at the original resolution.

6. The method of claim 1, further comprising:
rendering for display a three-dimensional visualization of well segments and completion devices of the identified well.

7. The method of claim 1, further comprising:
generating commands to adjust settings of completion devices installed in the identified well based on the simulated production.

8. The method of claim 1, wherein the first area comprises reservoir simulation grid points within a specified radius surrounding the location of the identified well within the reservoir simulation grid.

9. A system for modeling complex well completions, the system comprising:
at least one processor; and
a memory storing instructions that, when executed by the at least one processor, cause the at least one processor to perform operations comprising:
identifying a well that is a candidate for receiving a complex well completion, the complex well completion including completion devices configured to alter a production from the well;
generating initial configuration data representing completion devices for the well;
modeling the well as a set of wellbore segments, the set of wellbore segments defining a well network, wellbore segments of the set of wellbore segments being modeled to represent completion devices based on the initial configuration data;
integrating the well network into a reservoir simulation grid by locating the wellbore segments within the simulated reservoir at particular locations within the reservoir simulation grid;
selecting a portion of the well network comprising at least one wellbore segment, the portion of the well network within a first area of the reservoir simulation grid;
refining the reservoir simulation grid within the first area that includes the selected at least one wellbore segment;
coarsening the reservoir simulation grid in a second area of the reservoir simulation grid outside of the first area that includes the at least one wellbore segment;
executing a simulation of the reservoir simulator, the simulation generating production data representing the production from the well, wherein the refining provides data at a high resolution at the first area, and wherein the coarsening enables a reduction in processing resources relative to the processing resources required for the first area; and
rendering for display a simulated production profile of the well.

10. The system of claim 9, wherein the operations further comprise:
changing values of parameters of the configuration of completion devices;
iteratively performing the executing and the changing until a value of an objective function meets a prespecified criterion; and
selecting a final configuration of completion devices based on a latest iteration of performing meeting the prespecified criterion.

11. The system of claim 10, wherein parameters of the configuration of completion devices comprise at least one of locations of completion devices, types of completion devices, and a number of completion devices.

12. The system of claim 10, wherein the objective function comprises at least one of a water cut, a total oil production, a net present value of oil in the reservoir, an oil production in compartments of the well, a gas breakthrough, and a water breakthrough.

13. The system of claim 9, wherein the operations further comprise:
generating commands to adjust settings of completion devices installed in the identified well based on the simulated production.

14. The system of claim 9, wherein the first area comprises reservoir simulation grid points within a specified radius surrounding the location of the identified well within the reservoir simulation grid.

15. One or more non-transitory machine-readable storage devices storing instructions for modeling complex well completions, the instructions being executable by one or more processors, to cause performance of operations comprising:
identifying a well that is a candidate for receiving a complex well completion, the complex well completion including completion devices configured to alter a production from the well;
generating initial configuration data representing completion devices for the well;
modeling the well as a set of wellbore segments, the set of wellbore segments defining a well network, wellbore segments of the set of wellbore segments being modeled to represent completion devices based on the initial configuration data;
integrating the well network into a reservoir simulation grid by locating the wellbore segments within the simulated reservoir at particular locations within the reservoir simulation grid;
selecting a portion of the well network comprising at least one wellbore segment, the portion of the well network within a first area of the reservoir simulation grid;
refining the reservoir simulation grid within the first area that includes the selected at least one wellbore segment;
coarsening the reservoir simulation grid in a second area of the reservoir simulation grid outside of the first area that includes the at least one wellbore segment;
executing a simulation of the reservoir simulator, the simulation generating production data representing the production from the well, wherein the refining provides data at a high resolution at the first area, and wherein the coarsening enables a reduction in processing resources relative to the processing resources required for the first area; and
rendering for display a simulated production profile of the well.

16. The non-transitory machine-readable storage devices of claim 15, wherein the operations further comprise:
changing values of parameters of the configuration of completion devices;
iteratively performing the executing and the changing until a value of an objective function meets a prespecified criterion; and
selecting a final configuration of completion devices based on a latest iteration of performing meeting the prespecified criterion.

17. The non-transitory machine-readable storage devices of claim 16, wherein parameters of the configuration of completion devices comprise at least one of locations of completion devices, types of completion devices, and a number of completion devices.

18. The non-transitory machine-readable storage devices of claim 16, wherein the objective function comprises at least one of a water cut, a total oil production, a net present value of oil in the reservoir, an oil production in compartments of the well, a gas breakthrough, and a water breakthrough.

19. The non-transitory machine-readable storage devices of claim 15, wherein the operations further comprise:
generating commands to adjust settings of completion devices installed in the identified well based on the simulated production.

20. The non-transitory machine-readable storage devices of claim 15, wherein the first area comprises reservoir simulation grid points within a specified radius surrounding the location of the identified well within the reservoir simulation grid.
